(19) United States
(12) Patent Application Publication
(10) Pub. No.: US 2024/0423011 A1
(43) Pub. Date: Dec. 19, 2024

(54) PLANAR LIGHT-EMITTING TRANSISTOR DEVICE CAPABLE OF SURFACE LIGHT SOURCE EMISSION, AND PREPARATION METHOD THEREFOR AND APPLICATION THEREOF

(71) Applicant: INSTITUTE OF CHEMISTRY, CHINESE ACADEMY OF SCIENCES, Beijing (CN)

(72) Inventors: Huanli DONG, Beijing (CN); Zhagen MIAO, Beijing (CN); Haikuo GAO, Beijing (CN); Wenping HU, Beijing (CN); Can GAO, Beijing (CN); Man ZHAO, Beijing (CN)

(21) Appl. No.: 18/705,727

(22) PCT Filed: Oct. 27, 2022
(86) PCT No.: PCT/CN2022/127967

§ 371 Date: Apr. 29, 2024

(30) Foreign Application Priority Data
Nov. 2, 2021 (CN) 202111288584.3
Dec. 1, 2021 (CN) 202111460089.6

(51) Int. Cl. H10K 50/30; C09K 11/02; C09K 11/06; H10K 85/20; H10K 85/30; H10K 85/60

(52) U.S. Cl. CPC H10K 50/30; C09K 11/02; C09K 11/06; H10K 85/215; H10K 85/342; H10K 85/622; H10K 85/626; H10K 85/631; H10K 85/654; H10K 85/6576; C09K 2211/1007; C09K 2211/1011; C09K 2211/1029; C09K 2211/185

(57) ABSTRACT

A planar light-emitting transistor device capable of surface light source emission, and a preparation method therefor and an application thereof are provided. The planar light-emitting transistor device has a charge buffer layer inserted between a semiconductor charge transport layer and a light-emitting unit, such that a prepared planar light-emitting transistor can realize stable surface light source emission, thereby effectively overcoming the defect of the emergent light of a traditional planar light-emitting transistor being linear or strip-shaped. The planar light-emitting transistor device capable of surface light source emission has a high integration level, can realize stable surface light source emission, effectively improves the aperture ratio of the transistor device, has a good gate tunable capability, high loop stability and any tunability, and can be easily miniaturized.

The present application claims priority to the following two prior applications: patent application No. 202111288584.3 filed with China National Intellectual Property Administration by the applicant on Nov. 2, 2021 and entitled with “PLANAR LIGHT-EMITTING TRANSISTOR DEVICE CAPABLE OF SURFACE LIGHT SOURCE EMISSION, AND PREPARATION METHOD THEREFOR AND APPLICATION THEREOF”; and patent application No. 202111460089.6 filed with China National Intellectual Property Administration by the applicant on Dec. 1, 2021 and entitled with “PLANAR LIGHT-EMITTING TRANSISTOR DEVICE CAPABLE OF SURFACE LIGHT SOURCE EMISSION, AND PREPARATION METHOD THEREFOR AND APPLICATION THEREOF”, which are incorporated herein by reference in their entireties.

### TECHNICAL FIELD

The present disclosure belongs to the field of electroluminescent devices, and particularly relates to a planar light-emitting transistor capable of surface light source emission, a preparation method therefor and use thereof.

### BACKGROUND

The display industry has become a mainstay of the information technology industry. The light-emitting transistor, as a highly integrated electroluminescent device in which the current amplification function of the organic transistor and the electroluminescent function of the organic light-emitting diode are combined in a single device, has the unique advantages of high integration level, simple preparation process and the like, and is considered as an important device element of the next-generation revolutionary display technology for realizing miniaturization, flexibility, and high resolution.

At present, the classic configurations of light-emitting transistors are divided into a planar configuration and a vertical configuration. The vertical light-emitting transistor has a short channel, so that low-voltage driving and surface light source emission are easily realized, but the working mechanism of the vertical light-emitting transistor requires a porous source electrode that is difficult to prepare, so that the stability and uniformity of the device are influenced. The planar light-emitting transistor process has relatively good compatibility with existing industries, and the device is relatively stable, however, because electrons and holes of the planar light-emitting transistor are generally compounded on one side of a channel and an electrode, resulting in light emitting in the form of a line source, which is unsuitable for display applications.

How to realize a light-emitting transistor with both good device processability and stability and stable surface light source emission by reasonable design of the device structure has become an urgent technical problem to be solved in the art.

### Content of the Disclosure

The present disclosure provides a planar light-emitting transistor capable of surface light source emission, which comprises a source electrode, a drain electrode, and a charge buffer layer arranged under the source electrode or the drain electrode.

According to an embodiment of the present disclosure, the planar light-emitting transistor capable of surface light source emission further comprises a semiconductor charge transport layer.

Preferably, the semiconductor charge transport layer is arranged under the source electrode. In one embodiment of the present disclosure, the charge buffer layer is arranged over the semiconductor charge transport layer.

According to an embodiment of the present disclosure, the transistor further comprises a light-emitting unit. Preferably, the light-emitting unit is arranged under the drain electrode.

In one embodiment of the present disclosure, the charge buffer layer is arranged under the light-emitting unit. In another embodiment of the present disclosure, the charge buffer layer is arranged under the source electrode and the light-emitting unit.

According to an embodiment of the present disclosure, the charge buffer layer can be arranged between the drain electrode (or the source electrode) and the semiconductor charge transport layer, or between the semiconductor charge transport layer and the light-emitting unit.

According to an embodiment of the present disclosure, the transistor has a U-shaped light-emitting surface (comprising the light-emitting unit), and the source electrode is arranged on the side of a U-shaped aperture.

According to one embodiment of the present disclosure, the drain electrode, the light-emitting unit, and the charge buffer layer are U-shaped in a plane view, and the source electrode is arranged on the side of a U-shape aperture.

According to another embodiment of the present disclosure, the drain electrode and the light-emitting unit are U-shaped in a plane view, and the source electrode is arranged on the side of a U-shape aperture. Preferably, the charge buffer layer is arranged under the source electrode.

Preferably, the planar light-emitting transistor capable of surface light source emission comprises:
a support substrate;
a gate electrode arranged on the surface of the support substrate;
a dielectric layer arranged over the gate electrode;
a semiconductor charge transport layer arranged over the dielectric layer;
a source electrode and a charge buffer layer arranged over the semiconductor charge transport layer, wherein preferably, the source electrode and the charge buffer layer are arranged on different sides of the charge transport layer; and
a light-emitting unit and a drain electrode sequentially arranged over the charge buffer layer.

Preferably, the planar light-emitting transistor capable of surface light source emission comprises:
a support substrate;
a gate electrode arranged on the surface of the support substrate;
a dielectric layer arranged over the gate electrode;
a semiconductor charge transport layer arranged over the dielectric layer;
a charge buffer layer arranged over the semiconductor charge transport layer;
a source electrode and a light-emitting unit sequentially arranged over the charge buffer layer, wherein preferably, the source electrode and the light-emitting unit are arranged on different sides of the charge buffer layer; and
a drain electrode arranged over the light-emitting unit.

It should be noted that when an element such as a layer, a film, a crystal, a region, or a substrate plate is referred to as being “over/under another element” or “between two elements”, it can be directly placed over/under another element, or there may be one or more intervening layers.

According to an embodiment of the present disclosure, the source electrode and the drain electrode are arranged in a non-planar manner, that is, there is a height difference between them. For example, the source electrode and the charge buffer layer are both located over the semiconductor charge transport layer, optionally a gap is present or absent between the two, optionally they have the same or different thicknesses, and optionally the charge buffer layer covers the source electrode or the two are independent of each other; the drain electrode is arranged over the charge buffer layer (the drain electrode may completely cover or partially cover the charge buffer layer), and a conductive channel is formed between the drain electrode and the source electrode; optionally, a light-emitting unit is arranged between the drain electrode and the charge buffer layer, and the light-emitting unit may completely cover or partially cover the charge buffer layer and/or the source electrode. For example, the source electrode and the light-emitting unit are both arranged over the charge buffer layer, the drain electrode is arranged over the light-emitting unit, a conductive channel is formed between the drain electrode and the source electrode, optionally the source electrode and the light-emitting unit have the same or different thicknesses, optionally a gap is present or absent between the light-emitting unit and the source electrode, and optionally the light-emitting unit covers the source electrode or the two are independent of each other. A light-emitting part is the entire effective area of the source electrode or the drain electrode, and a gate voltage can be used to regulate luminous brightness.

According to an embodiment of the present disclosure, the charge buffer layer and the source electrode can be arranged on different sides of the semiconductor charge transport layer. The inventors firstly propose the introduction of the charge buffer layer and the position thereof, and the thickness and the area of the charge buffer layer and other layers can be adjusted by those skilled in the art according to actual needs.

According to an embodiment of the present disclosure, the semiconductor charge transport layer is made from a material with good electrical properties. Preferably, the semiconductor charge transport layer has a mobility of not less than 0.1 cm² V⁻¹ s⁻¹. For example, the semiconductor charge transport layer comprises an organic semiconductor material and/or an inorganic semiconductor material. For example, the organic semiconductor material is selected from a small molecule material and/or a polymer material.

Preferably, the organic semiconductor material is selected from one or more of the following, including, but not limited to: 2,7-dioctyl[1]benzothieno[3,2-b]benzothiophene (C₈-BTBT), 2,6-diphenylanthracene (DPA), 2,6-dinaphthylanthracene (dNaAnt), 2,6-di(p-n-hexylbenzene) anthracene (C₆-DPA), 2,6-di(p-octylhexylbenzene) anthracene (C₈-DPA), 2,6-di(p-decylbenzene) anthracene (C₁₀-DPA), poly(3-hexylthiophene) (P3HT), 9,9-di-n-octylfluorene-benzothiadiazole copolymer (F8BT), and poly[2,5-(2-octyldodecyl)-3,6-diketopyrrolopyrrole-alt-5,5-(2,5-di(thiophen-2-yl) thieno[3,2-b]thioph ene)](DPP-DTT), further preferably C₈-BTBT.

Preferably, the inorganic semiconductor material is selected from one or more of the following including, but not limited to: carbon nanotubes (CNTs), zinc-tin-oxide (ZTO), gallium nitride (GaN), silicon carbide (SiC), and zinc selenide (ZnSe).

According to an embodiment of the present disclosure, the charge buffer layer is made from a material with suitable electrical properties, e.g., selected from one or more of low-mobility organic materials, metal materials, p-n-p junctions, and the like. Preferably, the low mobility refers to a mobility that is 2-5 orders of magnitude less than the mobility of the semiconductor charge transport layer. For example, the charge buffer layer is a layer formed of one or more of 4,4′-cyclohexylbis[N,N-bis(4-methylphenyl) aniline] (TAPC), N,N′-diphenyl-N,N′-(1-naphthyl)-1,1′-biphenyl-4,4′-diamine (NPB), and polyvinylcarbazole (PVK) of the low-mobility organic materials, preferably a layer formed of TAPC. For another example, the metal material has a work function that matches the highest occupied molecular orbital (HOMO) level of the light-emitting unit and can be defined in a range of 4.5-6 eV. Preferably, the charge buffer layer is a layer formed of one or more of Au, e.g. Au, Ni, Pt, and the like of the metal materials, e.g., an ultra-thin layer, which may have a thickness of 0.5-10 nm, e.g., 1 nm, 2 nm, or 3 nm. For further example, the charge buffer layer is a layer formed of one or more of C60-pentacene-C60, C70-tetracene-C70, C60-tetracene-C70, and the like of the p-n-p junctions.

According to an embodiment of the present disclosure, when the material in the charge buffer layer is a low-mobility organic material or a p-n-p junction, the charge buffer layer has a thickness of 20-80 nm, e.g., 30 nm, 40 nm, or 50 nm.

According to an embodiment of the present disclosure, the light-emitting unit comprises a light-emitting layer, and an electron transport layer, a hole transport layer, an electron injection layer, and/or a hole injection layer that are matched to energy levels of the light-emitting layer.

Further, the light-emitting layer may be a layer formed of a light-emitting material having a light-emitting mechanism known in the art. For example, the light-emitting material is selected from one or more materials including, but not limited to, a fluorescent material, a phosphorescent material, a thermally activated delayed fluorescent material, and the like.

Preferably, the fluorescent material is selected from one or more of octahydroxyquinoline aluminum (Alq₃), 5,6,11,12-tetraphenyltetracene (i.e., Rubrene), and 4,4′-bis[4-(diphenylamino) styryl]biphenyl (BDAVBi).

Preferably, the phosphorescent material is selected from one or more of tris(2-phenylpyridine)iridium (Ir(ppy)₃), bis(2-phenylpyridine-C2,N)acetylacetonate iridium (Ir(ppy)₂(acac)), and iridium (III) tris[N,N′-diphenylbenzimidazol-2-ylidene-C2,C2′] (Ir(dpbic)₃).

Preferably, the thermally activated delayed fluorescent material is selected from one or two of 9,9′-(5-(4,6-diphenyl-1,3,5-triazin-2-yl)-1,3-phenylene)bis(9H-carbazole) (DCzTRZ), (N-phenoxazine) phenyl]thiosulfone (PXZ-DPS), and 10-(4-(4,6-diphenyl-1,3,5-triazol-2-yl)phenyl)-9,9-dimethyl-9,10-dihydroacridine (DMAC-TRZ).

Further, the light emitted by the light-emitting unit has a spectrum in a range of 390-780 nm.

For another example, the light-emitting layer in the light-emitting unit may be a single light-emitting material or a guest-doped host material. In the present disclosure, the term “doped” means that a material of any one layer having a different physical property from a material accounting for the maximum weight percentage of a respective layer is added, in an amount corresponding to a weight percentage of not more than 30%, to the material accounting for the maximum weight percentage. The host material and the dopant material of any one layer are distinguishable from each other.

According to an embodiment of the present disclosure, the single light-emitting material is preferably Alq₃, DPA, or dNaAnt; the guest doping material in the guest-doped host material can be one or more materials, and the host material can be a single substance or a mixture; the guest doping material is preferably one or more of 1,4-bis(10-phenylanthren-9-yl)benzene (BD-1), BDAVBi, Perylene, bis-dimethyl-dihydroacridine phenylsulfone (DMAC-DPS), bis[2-(5-cyano-4,6-difluorophenyl)pyridine-C2, N]picolinate iridium (FCNirPic), iridium (III) bis[(2,3,4-difluorophenyl)-pyridine-N,C2′]picolinate (Ir(tfpd)₂pic), bis[2,4-dimethyl-6-(4-methyl-2-quinolyl-κN)phenyl-KC](2,2,6,6-tetramethyl-3,5-heptanedione-KO₃ (Ir(mphmq)₂tmd), 4,4′-bis[4-(di-p-tolylamino) styryl]biphenyl (DPAVBi), 9,9′-(5-(4,6-diphenyl-1,3,5-triazin-2-yl)-1,3-benzene)bis(9H-carbazole) (DCzTrz), 5,5-dibromo-4,4-di(tetradecyl)-2,2-bithiophene (fac-Ir(dpbic)₃), tris(2-phenylpyridine)iridium (Ir(ppy)₃), tris[2-(p-tolyl)pyridine] iridium (III) (Ir(mppy)₃), bis(2-phenylpyridine-C2,N) acetylacetonate iridium (III) (Ir(ppy)₂(acac)), bis(2-(naphthalen-2-yl)pyridine) (acetylacetonate) iridium (III) (Ir(npy)₂acac), tris[2-(3-methyl-2-pyridyl)phenyl] iridium (Ir(3mppy)₃), bis(2-(3,5-dimethylphenyl) quinoline-C2,N′) (acetylacetonate) iridium (III) (Ir(dmpq)₂acac), (Ir(btp)₂(acac)), bis(2-(2′-benzothienyl)-pyridine-N,C3′) iridium (acetylacetonate) 4-(dicyanomethylene)-2-methyl-6-[2-(2,3,6,7-tetrahydro-1H,5H-benzo[ij] quinolizin-9-yl) vinyl]-4H-py (DCM2), 5,6,11,12-tetraphenyltetracene (i.e., Rubrene), ran tris(2-(3,5-dimethylphenyl) quinoline-C2,N′) iridium (III) (Ir(dmpq)₃), and 2,8-di-tert-butyl-5,11-bis(4-tert-butylphenyl)-6,12-diphenyltetracene (TBRb); the host material is preferably one or more of Alq₃, 4,4′-bis(N-carbazole)-1,1′-biphenyl (CBP), 4,4′-bis(2,2-diphenyl-ethen-1-yl)-4,4′-dimethylphenyl (p-DMDPVBi), 4,4′-bis(2,2-distyryl)-1,l′-biphenyl (DPVBi), 2-tert-butyl-9,10-bis(2-naphthyl) anthracene (TBADN), diphenyl[4-(triphenylsilyl)phenyl]phosphine oxide (TSPO1), 3-(3-(9H-carbazol-9-yl)phenyl)benzofuran[2,3-b]pyridine (PCz-BFP), 2,4,6-tris[3-(diphenylphosphinyloxy)phenyl]-1,3,5-triazole (PO-T2T), 2,4,6-tris(3-(carbazol-9-yl)phenyl)-1,3,5-triazine (TCPZ), 4,4′-bis(triphenylsilyl)-1,1′-biphenyl (BSB), 2,7-bis[9,9-bis(4-methylphenyl)-fluoren-2-yl]-9,9-bis(4-methylphenyl) fluorene (TDAF), 3′,3″,3″′-(1,3,5-triazine-2,4,6-triyl)tris(([1,1′-biphenyl]-3-carbonitrile)) (CN-T2T), and 10-(4-(4,6-diphenyl-1,3,5-triazol-2-yl)phenyl)-9,9-dimethyl-9,10-dihydroacridine (DMAC-TRZ).

Preferably, the light-emitting unit is a green light-emitting unit 10% Ir(ppy)₃:CBP/3TPYMB, a red light-emitting unit 5% Ir(mphmq)₂tmd:CBP/Tmpypb, or a blue light-emitting unit 10% BD-1:CBP/B3pypb, exemplarily 20 nm 10% Ir(ppy)₃:CBP/40 nm 3TPYMB, 20 nm 5% Ir(mphmq)₂tmd:CBP/40 nm Tmpypb, or 20 nm 10% BD-1:CBP/40 nm B3pypb.

In one embodiment, the light-emitting unit is a white light-emitting unit, for example, 2% Rubrene:DMAC-TRZ/3TPYMB, and for another example, 30 nm 2% Rubrene:DMAC-TRZ/40 nm 3TPYMB.

According to an embodiment of the present disclosure, the semiconductor charge transport layer, the charge buffer layer, and the light-emitting unit can be obtained by employing processing methods known in the art that facilitate charge transport and visible light emission, including, but not limited to, vacuum thermal evaporation, physical vapor transport, solution shearing, solution epitaxy, spin coating, and inkjet printing. It can be understood by those skilled in the art that the specific method employed can be specifically selected according to the physical properties (e.g., solubility, melting or boiling point, etc.) of the semiconductor material actually employed.

For example, the method for preparing an active layer including the semiconductor charge transport layer, the charge buffer layer, and the light-emitting unit may be selected from any one of the following methods:
method I: depositing a film of a small molecule material on the dielectric layers and electrodes described above by vacuum thermal evaporation in an evaporation cavity to obtain the active layer;
method II: spin-coating a solution of an active layer material on the dielectric layers and electrodes described above by spin coating to obtain the active layer;
method III: preparing and growing a monocrystal film of a small molecule material by solution epitaxy: dissolving the small molecule material in a solvent that is not miscible with water, slowly adding the obtained uniformly mixed solution dropwise to a water surface, spreading the mixed solution on the water surface, and volatilizing the solvent to obtain the monocrystal film; inserting a support substrate with a dielectric layer into water, and transferring the monocrystal film to the surface of the dielectric layer to obtain the active layer; and
method IV: preparing a monocrystal film of a small molecule material by solution shearing: dissolving the small molecule material in an organic solvent, adding the obtained uniformly mixed solution dropwise to a support substrate with a dielectric layer, and slowly shearing and stretching the added solution to form an active layer.

The charges are injected from an electrode (taking a source electrode as an example) at one end of the semiconductor charge transport layer, and are transported to the other end in an extremely thin conductive channel formed under an externally applied gate voltage, so as to form relatively uniform current injection under another electrode (taking a drain electrode as an example) through the action of the charge buffer layer, which is compounded with electrons injected by the drain electrode to form uniform surface light source emission.

According to an embodiment of the present disclosure, the semiconductor charge transport layer, the charge buffer layer, and the light-emitting unit all have a thickness of nanometer to submicron level. For example, the layers can each independently have a thickness of 5-500 nm, e.g., 10-100 nm.

According to an embodiment of the present disclosure, the light-emitting components (referring to the charge buffer layer and the light-emitting unit) are in a number of at least one, e.g., two, three, or more. When the light-emitting components are in a number of two, three, or more, the charge buffer layer and the light-emitting unit therein are optionally the same or different. The light-emitting components are connected through a charge generation layer (CGL).

According to an embodiment of the present disclosure, the source electrode, the drain electrode, and the gate electrode of the planar light-emitting transistor capable of surface light source emission can be transparent electrodes or opaque electrodes, and are each independently selected from any one or more of the following: metals, e.g., magnesium, calcium, sodium, potassium, titanium, indium, yttrium, lithium, gadolinium, aluminum, silver, tin, nickel, gold, molybdenum, iron, and lead; alloys of the foregoing metals; multilayer materials, e.g., LiF/Al, LiO₂/Al, or LiF/Al/Ag; metal oxides, e.g., ITO, IZO, MoOs, etc.; and heavily doped silicon. It can be understood by those skilled in the art that the specific type of metal selected can be adjusted according to the energy band of the semiconductor material.

According to an embodiment of the present disclosure, the source electrode, the drain electrode, and the gate electrode are prepared by methods known in the art. For example, at least one of vacuum thermal evaporation, inkjet printing, electron beam deposition, and the like can be selected.

According to an embodiment of the present disclosure, the dielectric layer is not particularly limited in the type, and can be an inorganic material dielectric layer and/or an organic material dielectric layer. Illustratively, the dielectric layer is an inorganic material dielectric layer, e.g., a dielectric layer formed of an inorganic oxide (Al₂O₃ or SiO₂); and/or the dielectric layer is an organic material dielectric layer, e.g., a dielectric layer formed of polymethylmethacrylate (PMMA).

According to an embodiment of the present disclosure, the dielectric layer can be prepared by methods known in the art. For example, at least one of thermal growth, physical vapor deposition, spin coating, and the like can be selected.

According to an embodiment of the present disclosure, the dielectric layer is not particularly limited in the thickness. Illustratively, the dielectric layer has a thickness of 10-800 nm. The thickness of the dielectric layer can be adjusted by those skilled in the art according to actual needs.

According to an embodiment of the present disclosure, the support substrate is a rigid substrate (e.g., a silicon dioxide sheet, glass, quartz, etc.) or a flexible substrate (e.g., PC, PMMA, PDMS, etc.).

According to an embodiment of the present disclosure, the planar light-emitting transistor capable of surface light source emission can have a device structure of top or bottom light emission.

According to an embodiment of the present disclosure, the planar light-emitting transistor capable of surface light source emission can emit a planar light matched in color to the light-emitting unit under an externally applied voltage.

The present disclosure also provides a preparation method for the planar light-emitting transistor capable of surface light source emission described above, which comprises the following steps: arranging a charge buffer layer under a drain electrode or a source electrode, wherein the drain electrode, the source electrode, and the charge buffer layer all have the meanings as indicated above.

According to an embodiment of the present disclosure, the preparation method comprises the following steps: arranging a charge buffer layer between a drain electrode (or a source electrode) and a semiconductor charge transport layer, or between the semiconductor charge transport layer and a light-emitting unit, wherein
the drain electrode, the source electrode, the semiconductor charge transport layer, the light-emitting unit, and the charge buffer layer all have the meanings as indicated above.

Preferably, a structure comprising the semiconductor charge transport layer, the charge buffer layer, and the light-emitting unit is taken as an active layer, wherein the active layer is prepared by the schemes described above.

The transistor device of the present disclosure has good compatibility with low-temperature processing techniques, such as solution processing techniques (inkjet printing, electrofluidic printing, reel-to-reel, etc.).

The present disclosure also provides use of the planar light-emitting transistor capable of surface light source emission described above in wearable devices.

The present disclosure also provides use of the planar light-emitting transistor capable of surface light source emission described above in the fields of illumination display, optical communication, novel optoelectronic integration and the like. For example, the other related application fields include lasers and the like.

The present disclosure also provides use of the planar light-emitting transistor capable of surface light source emission described above in the field of illumination, e.g., white-light illumination.

The planar light-emitting transistor capable of surface light source emission described above may be a transistor comprising one light-emitting component or a transistor comprising at least two light-emitting components connected in series.

### Beneficial Effects of Present Disclosure

In terms of conventional planar light-emitting transistors, most of their devices emit linear or strip-shaped light, and a good surface light source cannot be well present. In order to overcome the defects of the conventional light-emitting transistors, the present disclosure provides a light-emitting transistor with a charge buffer layer. The inventors of the present application have found that by inserting a charge buffer layer under a source electrode or a drain electrode, between a drain electrode (or a source electrode) and a semiconductor charge transport layer, or between a charge transport layer and a light-emitting unit, the current density could be redistributed in the transistor, and the prepared planar light-emitting transistor could achieve stable surface light source emission, providing uniform RGB area emission. At the same time, it has good gate tunability (on/off ratio: 10⁶), high loop stability, and any tunability, and has a high aperture ratio that can be adjusted according to actual needs, such as adjusted from no less than 10% of the prior art to more than 94%. Due to the flexibility of the organic semiconductor, the integration with the wearable device can be realized, which is more advantageous for expanding the functions and application scenarios of wearable light-emitting devices capable of surface light source emission.

1. The planar light-emitting transistor device capable of surface light source emission described herein can realize the surface light source emission without being influenced by gate voltage, which is favorable for the application of the device in the display field.

2. The planar light-emitting transistor device capable of surface light source emission described herein can realize the construction of an electroluminescent device with a high aperture ratio, can be well compatible with a flexible wearable device, and plays an important role in promoting the development of the light-emitting transistor device.

3. By developing the light-emitting transistor device capable of surface light source emission based on an organic semiconductor in the present disclosure, the advantages of rich system, light weight, low price, and easy processing of the organic semiconductor material can be used to the maximum extent, which provides an effective solution for the large-area controllable and arrayed preparation of light-emitting transistor devices.

The “aperture ratio” refers to the percentage of the area of a light-emitting surface to the sum of the areas of a light-emitting surface and an aperture surface. Transistors with a series of aperture ratios (e.g., 10%, 15%, 20%, 30%, 40%, 50%, 60%, 70%, 80%, 82%, 85%, 88%, 90%, or 94%) can be obtained by controlling the proportion of the area of the light-emitting surface.

### BRIEF DESCRIPTION OF THE DRAWINGS

FIG. 1-1 shows a schematic structure diagram of the light-emitting transistor devices capable of surface light source emission prepared in Examples 1-4.

FIG. 1-2 shows a schematic structure diagram of the light-emitting transistor devices capable of surface light source emission prepared in Example 5.

FIG. 2-1 shows optical micrographs of surface light source emissions of the planar light-emitting transistor devices of primary colors of red, green, and blue prepared in Example 1, Example 2, and Example 3, respectively.

FIG. 2-2 shows typical transfer curve (a), output curve (b), and emission spectrum (c) of the green planar light-emitting transistor device prepared in Example 1.

FIG. 3 shows an optical device photograph and an optical luminescence photograph of the planar light-emitting transistor with a high aperture ratio and surface light source emission in Example 4.

FIG. 4 shows typical transfer curve and emission spectrum of the high-aperture-ratio planar light-emitting transistor capable of surface light source emission in Example 4.

FIG. 5 shows a schematic structure diagram of the planar light-emitting tandem transistor capable of surface light source emission comprising three light-emitting components in Example 8.

FIG. 6 shows a schematic structure diagram (left) and an optical photograph (right, scale: 0.2 mm) of the light-emitting transistor capable of surface light source emission prepared in Example 9.

FIG. 7 shows a relation curve of source/drain current-brightness-gate voltage (left) and a relation graph of external quantum efficiency (EQE) and brightness (right) of the device in Example 9.

FIG. 8 shows luminescence photographs of the device in Example 9 at gate voltages of −5 V, −6 V, and −20 V.

### MODES FOR CARRYING OUT THE DISCLOSURE

The present disclosure will be further illustrated with reference to the following specific examples. It should be understood that these examples are merely intended to illustrate the present disclosure rather than limit the protection scope of the present disclosure. In addition, it should be understood that various changes or modifications may be made by those skilled in the art after reading the teachings of the present disclosure, and these equivalents also fall within the protection scope of the present disclosure.

Unless otherwise stated, the experimental methods used in the following examples are conventional methods. Unless otherwise stated, the reagents, materials, and the like used in the following examples are commercially available.

### Example 1. Planar Light-Emitting Transistor Device Capable of Surface Light Source Emission Based on CBP:Ir(ppy)₃ Green Light-Emitting Unit

### 1) Si/SiO₂ Sheet Cleaning and Water-Soluble Layer Modification:

Before use, a silicon wafer with a SiO₂ oxide layer was cleaned with hydrogen peroxide and concentrated sulfuric acid (heated by an electric furnace and boiled for 15 min) according to a volume ratio of 1:2, and then sequentially sonicated with deionized water, acetone, and isopropanol, each for about 10 min, and the silicon wafer was rapidly blown to dryness by using nitrogen. The surface energy level was modified in an O₂ plasma cleaner for 5 min and the residual organic solvent was removed from the surface. Then the silicon wafer was dried in an oven at 90° C. for 90 min. Finally, a drop of octadecyl trichlorosilane (OTS) was dripped with a capillary tube in the middle of a culture dish where the silicon wafer was placed, and the culture dish was placed in an oven at 120° C. for heating for 120 min, followed by natural cooling.

2) Preparation of organic charge transport layer (i.e., semiconductor charge transport layer) C₈-BTBT:

A patterned metal mask plate was fixed to a substrate, and 50 nm C₈-BTBT was thermally evaporated on the Si/SiO₂ sheet modified in the step 1) by a vacuum coating machine. After evaporation, an annealing treatment was performed immediately at 45° C. for 20 min.

### 3) Preparation of Source Electrode:

The mask plate was replaced with a new one, which was then fixed to the substrate, and 2 nm MoOₓ and 40 nm Au were thermally evaporated on one side of the organic charge transport layer by a vacuum coating machine.

### 4) Preparation of Charge Buffer Layer and Light-Emitting Unit:

The mask plate was replaced with a new one, which was then fixed to the substrate, and a charge buffer layer 40 nm TAPC and a light-emitting unit 20 nm 10% Ir(ppy)₃:CBP/40 nm 3TPYMB were sequentially deposited on the other side of the organic charge transport layer by a vacuum coating machine.

### 5) Preparation of Drain Electrode:

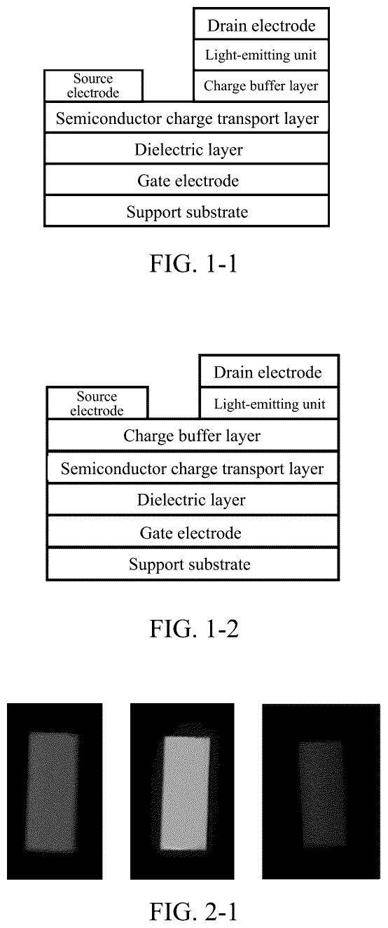

The mask plate was replaced with a new one, which was then fixed to the substrate, and 0.5 nm LiF/1 nm Al/35 nm Ag were sequentially deposited on the light-emitting unit by a vacuum coating machine to obtain a product serving as a drain electrode. The preparation of the device was completed. The structure of the device is shown in FIG. 1.

### 6) Performance Testing and Characterization of the Light-Emitting Transistor:

Under nitrogen atmosphere of a glove box, voltage was applied to the source electrode, the drain electrode, and the gate electrode separately by using a probe, wherein the gate electrode was heavily doped silicon, the source electrode was grounded, the voltage between the source electrode and the drain electrode was-70 V, and the voltage between the gate electrode and the source electrode was changed from 20 V to −70 V with a step length of −2 V; the photocurrent of the device was determined by using a photomultiplier tube at 0.5 V level in a dark environment, so that a relation curve of current-photocurrent-voltage of the device was determined. The spectrum of the device was determined by using a spectrometer, and a luminescence picture was acquired by using a CCD.

### Example 2. Planar Light-Emitting Transistor Device Capable of Surface Light Source Emission Based on CBP:Ir(mphmq)₂tmd Red Light-Emitting Unit

### 1) Si/SiO₂ Sheet Cleaning and Water-Soluble Layer Modification:

Before use, a silicon wafer with a SiO₂ oxide layer was cleaned with hydrogen peroxide and concentrated sulfuric acid (heated by an electric furnace and boiled for 15 min) according to a volume ratio of 1:2, and then sequentially sonicated with deionized water, acetone, and isopropanol, each for about 10 min, and the silicon wafer was rapidly blown to dryness by using nitrogen. The surface energy level was modified in an O₂ plasma cleaner for 5 min and the residual organic solvent was removed from the surface. Then the silicon wafer was dried in an oven at 90° C. for 90 min. Finally, a drop of octadecyl trichlorosilane (OTS) was dripped with a capillary tube in the middle of a culture dish where the silicon wafer was placed, and the culture dish was placed in an oven at 120° C. for heating for 120 min, followed by natural cooling.

### 2) Preparation of Organic Charge Transport Layer (i.e., Semiconductor Charge Transport Layer) C₈-BTBT:

A patterned metal mask plate was fixed to a substrate, and 50 nm C₈-BTBT was thermally evaporated on the Si/SiO₂ sheet modified in the step 1) by a vacuum coating machine. After evaporation, an annealing treatment was performed immediately at 45° C. for 20 min.

### 3) Preparation of Source Electrode:

The mask plate was replaced with a new one, which was then fixed to the substrate, and 2 nm MoOₓ and 40 nm Au were thermally evaporated on one side of the organic charge transport layer by a vacuum coating machine.

### 4) Preparation of Charge Buffer Layer and Light-Emitting Unit:

The mask plate was replaced with a new one, which was then fixed to the substrate, and a charge buffer layer 40 nm TAPC and a light-emitting unit 20 nm 5% Ir(mphmq)₂tmd:CBP/40 nm Tmpypb were sequentially deposited on the other side of the organic charge transport layer by a vacuum coating machine.

### 5) Preparation of Drain Electrode:

The mask plate was replaced with a new one, which was then fixed to the substrate, and 0.5 nm LiF/1 nm Al/35 nm Ag were sequentially deposited on the light-emitting unit by a vacuum coating machine to obtain a product serving as a drain electrode. The preparation of the device was completed. The structure of the device is shown in FIG. 1.

### 6) Performance Testing and Characterization of the Light-Emitting Transistor:

Under nitrogen atmosphere of a glove box, voltage was applied to the source electrode, the drain electrode, and the gate electrode separately by using a probe, wherein the gate electrode was heavily doped silicon, the source electrode was grounded, the voltage between the source electrode and the drain electrode was-70 V, and the voltage between the gate electrode and the source electrode was changed from 20 V to −70 V with a step length of −2 V; the photocurrent of the device was determined by using a photomultiplier tube at 0.5 V level in a dark environment, so that a relation curve of current-photocurrent-voltage of the device was determined. The spectrum of the device was determined by using a spectrometer, and a luminescence picture was acquired by using a CCD.

### Example 3. Planar Light-Emitting Transistor Device Capable of Surface Light Source Emission Based on CBP: BD-1 Blue Light-Emitting Unit

### 1) Si/SiO₂ Sheet Cleaning and Water-Soluble Layer Modification:

Before use, a silicon wafer with a SiO₂ oxide layer was cleaned with hydrogen peroxide and concentrated sulfuric acid (heated by an electric furnace and boiled for 15 min) according to a volume ratio of 1:2, and then sequentially sonicated with deionized water, acetone, and isopropanol, each for about 10 min, and the silicon wafer was rapidly blown to dryness by using nitrogen. The surface energy level was modified in an O₂ plasma cleaner for 5 min and the residual organic solvent was removed from the surface. Then the silicon wafer was dried in an oven at 90° C. for 90 min. Finally, a drop of octadecyl trichlorosilane (OTS) was dripped with a capillary tube in the middle of a culture dish where the silicon wafer was placed, and the culture dish was placed in an oven at 120° C. for heating for 120 min, followed by natural cooling.

### 2) Preparation of Organic Charge Transport Layer (i.e., Semiconductor Charge Transport Layer) C₈-BTBT:

A patterned metal mask plate was fixed to a substrate, and 50 nm C₈-BTBT was thermally evaporated on the Si/SiO₂ sheet modified in the step 1) by a vacuum coating machine. After evaporation, an annealing treatment was performed immediately at 45° C. for 20 min.

### 3) Preparation of Source Electrode:

The mask plate was replaced with a new one, which was then fixed to the substrate, and 2 nm MoOₓ and 40 nm Au were thermally evaporated on one side of the organic charge transport layer by a vacuum coating machine.

### 4) Preparation of Charge Buffer Layer and Light-Emitting Unit:

The mask plate was replaced with a new one, which was then fixed to the substrate, and a charge buffer layer 40 nm TAPC and a light-emitting unit 20 nm 10% BD-1:CBP/40 nm B3pypb were sequentially deposited on the other side of the organic charge transport layer by a vacuum coating machine.

### 5) Preparation of Drain Electrode:

The mask plate was replaced with a new one, which was then fixed to the substrate, and 0.5 nm LiF/1 nm Al/35 nm Ag were sequentially deposited on the light-emitting unit by a vacuum coating machine to obtain a product serving as a drain electrode. The preparation of the device was completed. The structure of the device is shown in FIG. 1.

### 6) Performance Testing and Characterization of the Light-Emitting Transistor:

Under nitrogen atmosphere of a glove box, voltage was applied to the source electrode, the drain electrode, and the gate electrode separately by using a probe, wherein the gate electrode was heavily doped silicon, the source electrode was grounded, the voltage between the source electrode and the drain electrode was-70 V, and the voltage between the gate electrode and the source electrode was changed from 20 V to −70 V with a step length of −2 V; the photocurrent of the device was determined by using a photomultiplier tube at 0.5 V level in a dark environment, so that a relation curve of current-photocurrent-voltage of the device was determined. The spectrum of the device was determined by using a spectrometer, and a luminescence picture was acquired by using a CCD.

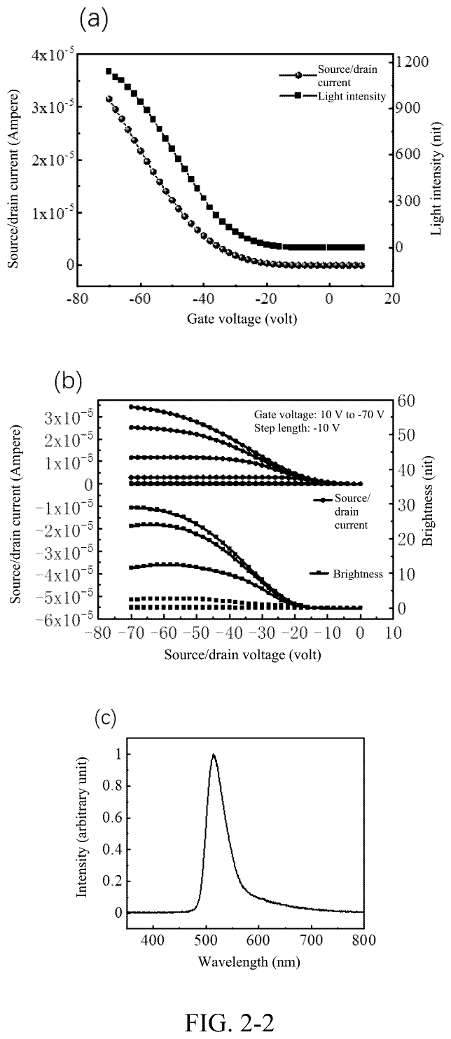

FIG. 2-1 shows optical micrographs of surface light emissions in a dark field of the planar light-emitting field-effect transistor devices of primary colors of red, green, and blue prepared in Example 1, Example 2, and Example 3, respectively, with colors from left to right being red, green, and blue sequentially, realizing the emission of the surface light source. FIG. 2-2 shows typical transfer curve, output curve, and emission spectrum of the green planar light-emitting field-effect transistor device prepared in Example 1, indicating good gate voltage regulation characteristics (on/off ratio: 10⁶) and light-emitting performance of the transistor device.

### Example 4. High-Aperture-Ratio Planar Light-Emitting Transistor Device Capable of Surface Light Source Emission Based on CBP:Ir(ppy)₃ Green Light-Emitting Unit

### 1) Si/SiO₂ Sheet Cleaning and Water-Soluble Layer Modification:

Before use, a silicon wafer with a SiO₂ oxide layer was cleaned with hydrogen peroxide and concentrated sulfuric acid (heated by an electric furnace and boiled for 15 min) according to a volume ratio of 1:2, and then sequentially sonicated with deionized water, acetone, and isopropanol, each for about 10 min, and the silicon wafer was rapidly blown to dryness by using nitrogen. The surface energy level was modified in an O₂ plasma cleaner for 5 min and the residual organic solvent was removed from the surface. Then the silicon wafer was dried in an oven at 90° C. for 90 min. Finally, a drop of octadecyl trichlorosilane (OTS) was dripped with a capillary tube in the middle of a culture dish where the silicon wafer was placed, and the culture dish was placed in an oven at 120° C. for heating for 120 min, followed by natural cooling.

### 2) Preparation of Organic Charge Transport Layer C₈-BTBT:

A patterned metal mask plate was fixed to a substrate, and 50 nm C₈-BTBT was thermally evaporated on the Si/SiO₂ sheet modified in the step 1) by a vacuum coating machine. After evaporation, an annealing treatment was performed immediately at 45° C. for 20 min.

### 3) Preparation of Source Electrode:

The mask plate was replaced with a new one, which was then fixed to the substrate, and 2 nm MoOₓ and 40 nm Au were thermally evaporated on one side of the organic charge transport layer by a vacuum coating machine.

### 4) Preparation of Charge Buffer Layer and Light-Emitting Unit:

The mask plate was replaced with a new one, which was then fixed to the substrate, and a charge buffer layer 40 nm TAPC and a light-emitting unit 20 nm 10% Ir(ppy)₃:CBP/40 nm 3TPYMB were sequentially deposited on the other side of the organic charge transport layer by a vacuum coating machine.

### 5) Preparation of Drain Electrode:

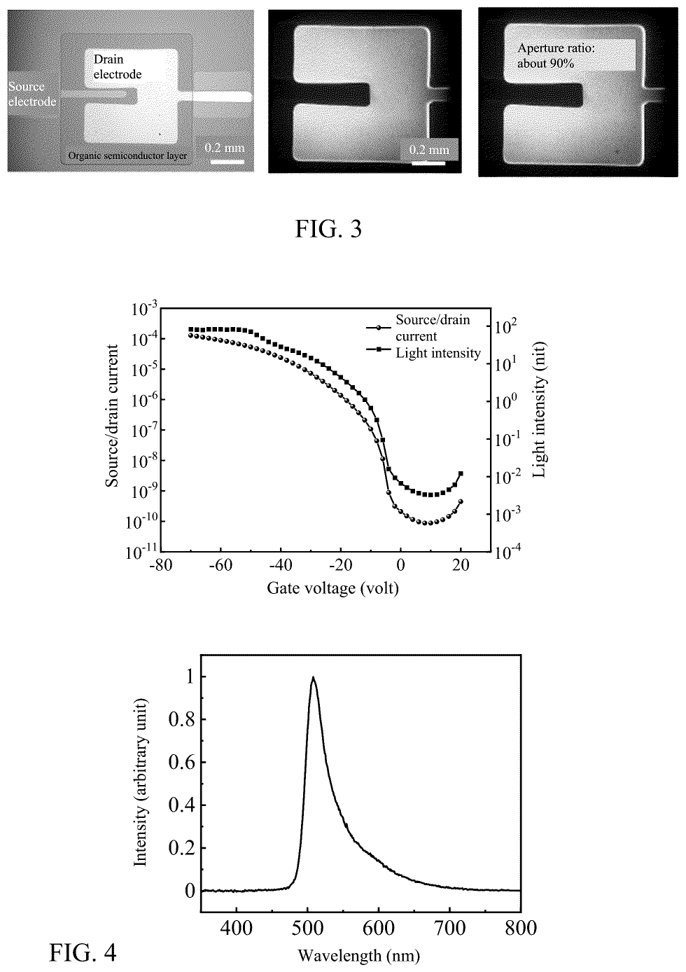

The mask plate was replaced with a new one, which was then fixed to the substrate, and 0.5 nm LiF/1 nm Al/35 nm Ag were sequentially deposited on the light-emitting unit by a vacuum coating machine to obtain a product serving as a drain electrode. The preparation of the device was completed. The structure of the device is shown in FIG. 1, and the optical photograph (left) and the optical luminescence photograph (right) of the obtained device are shown in FIG. 3.

### 6) Performance Testing and Characterization of the Light-Emitting Transistor:

Under nitrogen atmosphere of a glove box, voltage was applied to the source electrode, the drain electrode, and the gate electrode separately by using a probe, wherein the gate electrode was heavily doped silicon, the source electrode was grounded, the voltage between the source electrode and the drain electrode was-70 V, and the voltage between the gate electrode and the source electrode was changed from 20 V to −70 V with a step length of −2 V; the photocurrent of the device was determined by using a photomultiplier tube at 0.5 V level in a dark environment, so that a relation curve of current-photocurrent-voltage of the device was determined. The spectrum of the device was determined by using a spectrometer, and a bright-field photograph and a dark-field luminescence photograph were acquired by using a CCD. The test results are shown in FIG. 4, indicating that increasing the light-emitting area can improve the aperture ratio (aperture ratio of about 90%) while still realizing a better surface light source emission effect and luminous brightness, and the planar light-emitting transistor capable of surface light source emission can realize the construction of a device with a high aperture ratio.

### Example 5

The process of preparing the transistor in Example 4 was referred to. Unlike Example 4, in this example, a semiconductor charge transport layer was firstly deposited on a modified Si/SiO₂ sheet, a charge buffer layer was deposited, and then a source electrode and a light-emitting unit were deposited on the charge buffer layer, with the source electrode and the light-emitting unit being separately located on one side of the charge buffer layer, and finally a drain electrode was deposited on the light-emitting unit. The specific structure is shown in FIG. 1-2. After testing, it was determined that the transistor device obtained in this example also has good gate voltage regulation characteristics, light-emitting performance, great aperture ratio (aperture ratio up to at least 80%), and stability.

### Examples 6-7

The transistors in Examples 6-7 were prepared by using an ultra-thin metal material Au as a charge buffer layer instead of TAPC in Example 4, or using C60-pentacene-C60 as a charge buffer layer instead of TAPC in Example 4. The transistors have the same or similar performance as those in Example 4, that is, the transistorsare also a planar light-emitting transistor capable of surface light source emission, which has good gate voltage regulation characteristics, light-emitting performance, and stability.

### Example 8

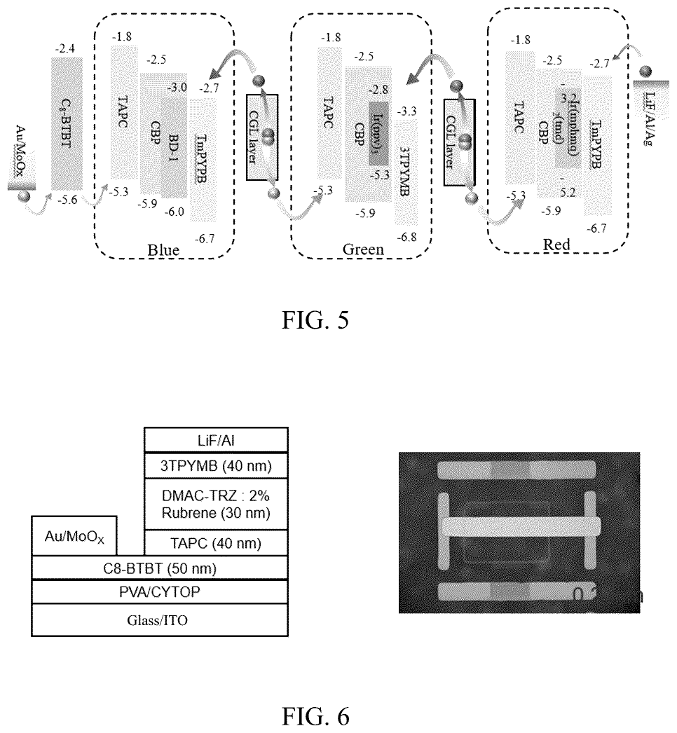

As shown in FIG. 5, the device in this example comprises a source electrode, an organic charge transport layer C₈-BTBT, three light-emitting components (a first light-emitting component: a charge buffer layer TAPC and a blue light-emitting unit BD-1:CBP/TmPTPB; a second light-emitting component: a charge buffer layer TAPC and a green light-emitting unit Ir(ppy)₃:CBP/3TPYMB; and a third light-emitting part: a charge buffer layer TAPC and a red light-emitting unit Ir(mphmq)₂tmd:CBP/Tmpypb), and a drain electrode LiF/Al/Ag. The light-emitting components are connected through a CGL layer.

### Example 9. Planar Light-Emitting Field-Effect Transistor Device Capable of Surface Light Source Emission Based on DMAC-TRZ:Rubrene White Light-Emitting Unit

### 1) Cleaning of Glass/Indium-Tin-Oxide (ITO) Sheet and Preparation of Dielectric Layer:

Before use, a glass sheet with an ITO layer was sequentially sonicated with deionized water, acetone, and isopropanol, each for about 10 min, and was blown to dryness by using nitrogen. The surface energy level was modified in an O₂ plasma cleaner for 5 min and the residual organic solvent was removed from the surface.

PVA powder (average Mw≈205,000 g mol⁻¹) was dissolved in deionized water (58 mg mL⁻¹), and the solution was stirred at 800 rmp for 6 h. Then glutaraldehyde (GA, 50 wt %) was added to the solution (volume ratio: 1:80). The glass/ITO substrate was spin-coated with the prepared PVA solution (4200 rmp×45 s) to obtain a 350 nm film. Then the film was thermally annealed in air at 100° C. for 90 min. Subsequently, the PVA layer (about 10 nm) was spin-coated with perfluororesin CYTOP (CTL-809M, type M) and annealed at 100° C. for 30 min.

### 2) Preparation of Organic Charge Transport Layer C₈-BTBT:

A patterned metal mask plate was fixed to a substrate, and 50 nm C₈-BTBT was thermally evaporated on the glass/ITO/dielectric layer by a vacuum coating machine.

### 3) Preparation of Source Electrode:

The mask plate was replaced with a new one, which was then fixed to the substrate, and 2 nm MoOₓ and 40 nm Au were thermally evaporated on glass/ITO/dielectric layer/C₈-BTBT by a vacuum coating machine.

### 4) Preparation of Charge Buffer Layer and Light-Emitting Unit:

The mask plate was replaced with a new one, which was then fixed to the substrate, and a 40 nm TAPC charge buffer layer and a light-emitting unit 30 nm 2% Rubrene:DMAC-TRZ/40 nm 3TPYMB were deposited on glass/ITO/dielectric layer/C₈-BTBT/MoOₓ/Au by a vacuum coating machine.

### 5) Preparation of Drain Electrode:

The mask plate was replaced with a new one, which was then fixed to the substrate, and 2 nm LiF/120 nm Al were deposited sequentially on glass/ITO/dielectric layer/C₈-BTBT/MoOₓ/Au/TAPC/2% Rubrene:DMAC-TRZ/40 nm 3TPYMB by a vacuum coating machine to obtain a product as a drain electrode. The preparation of the was completed. The schematic structure diagram (left) and the optical photograph (right) of the device are shown in FIG. 6.

### 6) Performance Testing and Characterization of the Light-Emitting Field-Effect Transistor:

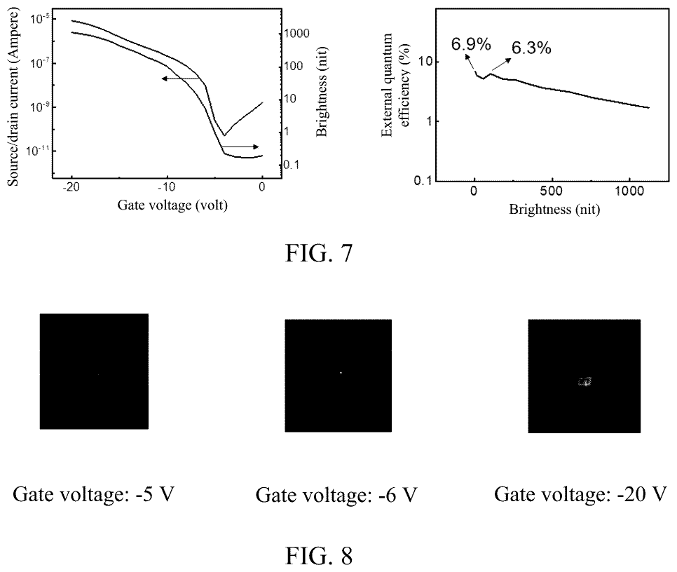

Under nitrogen atmosphere of a glove box, voltage was applied to the source electrode, the drain electrode, and the gate electrode separately by using a probe, wherein the gate electrode was ITO, the source electrode was grounded, the voltage between the source electrode and the drain electrode was-20 V, and the voltage between the gate electrode and the source electrode was changed from 0 V to −20 V with a step length of −1 V; the photocurrent of the device was determined by using a photomultiplier tube at 0.5 V level in a dark environment, so that a relation curve of current-photocurrent-voltage of the device was determined and the relation between external quantum efficiency (EQE) and brightness was calculated. As shown in FIG. 7, the maximum brightness of the device was 1121 nit, and the maximum EQE was up to 6.9%. The luminescence photographs of the device were acquired by using a mobile phone camera. The luminescence photographs of the device at the gate voltage of −5 V, −6 V, and −20 V are shown in FIG. 8, showing uniform white light emission, which is of great significance for the use of light-emitting transistors in the field of illumination.

The embodiments of the present disclosure have been described above. However, the present disclosure is not limited to the embodiments described above. Any modification, equivalent, improvement and the like made without departing from the spirit and principle of the present disclosure shall fall within the protection scope of the present disclosure.

1. A planar light-emitting transistor capable of surface light source emission, comprising a source electrode, a drain electrode, and a charge buffer layer arranged under the source electrode or the drain electrode.

2. The planar light-emitting transistor capable of surface light source emission as claimed in claim 1, wherein the planar light-emitting transistor capable of surface light source emission further comprises a semiconductor charge transport layer, wherein preferably, the semiconductor charge transport layer is arranged under the source electrode; further preferably, the charge buffer layer is arranged over the semiconductor charge transport layer;
preferably, the planar light-emitting transistor capable of surface light source emission further comprises a light-emitting unit, wherein preferably, the light-emitting unit is arranged under the drain electrode; further preferably, the charge buffer layer is arranged under the light-emitting unit, or the charge buffer layer is arranged under the source electrode and the light-emitting unit;
preferably, the charge buffer layer can be arranged between the drain electrode (or the source electrode) and the semiconductor charge transport layer, or between the semiconductor charge transport layer and the light-emitting unit;
preferably, the planar light-emitting transistor capable of surface light source emission comprises:
a support substrate;
a gate electrode arranged on the surface of the support substrate;
a dielectric layer arranged over the gate electrode;
a semiconductor charge transport layer arranged over the dielectric layer;
a source electrode and a charge buffer layer arranged over the semiconductor charge transport layer, wherein preferably, the source electrode and the charge buffer layer are arranged on different sides of the charge transport layer; and
a light-emitting unit and a drain electrode sequentially arranged over the charge buffer layer;
further preferably, the planar light-emitting transistor capable of surface light source emission comprises:
a support substrate;
a gate electrode arranged on the surface of the support substrate;
a dielectric layer arranged over the gate electrode;
a semiconductor charge transport layer arranged over the dielectric layer;
a charge buffer layer arranged over the semiconductor charge transport layer;
a source electrode and a light-emitting unit sequentially arranged over the charge buffer layer, wherein preferably, the source electrode and the light-emitting unit are arranged on different sides of the charge buffer layer; and
a drain electrode arranged over the light-emitting unit;
furthermore preferably, the source electrode and the drain electrode are arranged in a non-planar manner, a light-emitting part is the entire effective area of the source electrode or the drain electrode, and a gate voltage is used to regulate luminous brightness.

3. The planar light-emitting transistor capable of surface light source emission as claimed in claim 1, wherein the semiconductor charge transport layer has a mobility of not less than 0.1 cm² V⁻¹ s⁻¹;
preferably, the semiconductor charge transport layer comprises an organic semiconductor material and/or an inorganic semiconductor material, wherein for example, the organic semiconductor material is selected from a small molecule material and/or a polymer material;
preferably, the organic semiconductor material is selected from one or more of the following including, but not limited to: 2,7-dioctyl[1]benzothieno[3,2-b]benzothiophene (C₈-BTBT), 2,6-diphenylanthracene (DPA), 2,6-dinaphthylanthracene (dNaAnt), 2,6-di(p-n-hexylbenzene) anthracene (C₆-DPA), 2,6-di(p-octylhexylbenzene) anthracene (C₈-DPA), 2,6-di(p-decylbenzene) anthracene (C₁₀-DPA), poly(3-hexylthiophene) (P3HT), 9,9-di-n-octylfluorene-benzothiadiazole copolymer (F8BT), and poly[2,5-(2-octyldodecyl)-3,6-diketopyrrolopyrrole-alt-5,5-(2,5-di (thiophen-2-yl) thieno[3,2-b]thiophene)](DPP-DTT), further preferably C₈-BTBT;
preferably, the inorganic semiconductor material is selected from one or more of the following including, but not limited to: carbon nanotubes (CNTs), zinc-tin-oxide (ZTO), gallium nitride (GaN), silicon carbide (SiC), and zinc selenide (ZnSe).

4. The planar light-emitting transistor capable of surface light source emission as claimed in claim 1, wherein the charge buffer layer is made from a material selected from one or more of low-mobility organic materials, metal materials, and p-n-p junctions; preferably, the low mobility refers to a mobility that is 2-5 orders of magnitude less than the mobility of the semiconductor charge transport layer;
preferably, the charge buffer layer is a layer formed of one or more of 4,4′-cyclohexylbis[N,N-bis(4-methylphenyl) aniline] (TAPC), N,N′-diphenyl-N,N′-(1-naphthyl)-1,1′-biphenyl-4,4′-diamine (NPB), and PVK of the low-mobility organic materials, further preferably a layer formed of TAPC; or the charge buffer layer is a layer formed of one or more of Au, Ni, Pt, and the like of the metal materials; or the charge buffer layer is a layer formed of one or more of C60-pentacene-C60, C70-tetracene-C70, C60-tetracene-C70, and the like of the p-n-p junctions.

5. The planar light-emitting transistor capable of surface light source emission as claimed in claim 1, wherein the light-emitting unit comprises a light-emitting layer, and an electron transport layer, a hole transport layer, an electron injection layer, and/or a hole injection layer that are matched to energy levels of the light-emitting layer;
further, the light-emitting layer is a layer formed of a light-emitting material, wherein for example, the light-emitting material is selected from one or more materials including, but not limited to, a fluorescent material, a phosphorescent material, and a thermally activated delayed fluorescent material;
preferably, the fluorescent material is selected from one or more of octahydroxyquinoline aluminum (Alq₃), 5,6,11,12-tetraphenyltetracene, and 4,4′-bis[4-(diphenylamino) styryl]biphenyl (BDAVBi);
preferably, the phosphorescent material is selected from one or more of tris(2-phenylpyridine)iridium (Ir(ppy)₃), bis(2-phenylpyridine-C2,N)acetylacetonate iridium (Ir(ppy)₂(acac)), and iridium (III) tris[N,N′-diphenylbenzimidazol-2-ylidene-C2,C2′] (Ir(dpbic)₃);
preferably, the thermally activated delayed fluorescent material is selected from one or two of 9,9′-(5-(4,6-diphenyl-1,3,5-triazin-2-yl)-1,3-phenylene)bis(9H-carbazole) (DCzTRZ), (N-phenoxazine) phenyl]thiosulfone (PXZ-DPS), and 10-(4-(4,6-diphenyl-1,3,5-triazol-2-yl) phenyl)-9,9-dimethyl-9,10-dihydroacridine (DMAC-TRZ).

6. The planar light-emitting transistor capable of surface light source emission as claimed in claim 1, wherein the light emitted by the light-emitting unit has a spectrum in a range of 390-780 nm,
for another example, the light-emitting layer in the light-emitting unit is formed of a single light-emitting material or a guest-doped host material;
the single light-emitting material is preferably Alq₃, DPA, or dNaAnt; a guest doping material in the guest-doped host material is one or more of the following: 1,4-bis(10-phenylanthren-9-yl)benzene (BD-1), BDAVBi, Perylene, bis-dimethyl-dihydroacridine phenylsulfone (DMAC-DPS), bis[2-(5-cyano-4,6-difluorophenyl)pyridine-C2,N)] picolinate iridium (FCNirPic), iridium (III) bis[(2,3,4-difluorophenyl)-pyridine-N,C2′]picolinate (Ir(tfpd)₂pic), bis[2,4-dimethyl-6-(4-methyl-2-quinolyl-κN)phenyl-κC](2,2,6,6-tetramethyl-3,5-heptanedione-KO₃ (Ir(mphmq)₂tmd), 4,4′-bis[4-(di-p-tolylamino) styryl]biphenyl (DPAVBi), 9,9′-(5-(4,6-diphenyl-1,3,5-triazin-2-yl)-1,3-benzene)bis(9H-carbazole) (DCzTrz), 5,5-dibromo-4,4-di(tetradecyl)-2,2-bithiophene (fac-Ir(dpbic)₃), tris(2-phenylpyridine)iridium (Ir(ppy)₃), tris[2-(p-tolyl)pyridine] iridium (III) (Ir(mppy)₃), bis(2-phenylpyridine-C2,N)acetylacetonate iridium (III) (Ir(ppy)₂(acac)), bis(2-(naphthalen-2-yl)pyridine) (acetylacetonate) iridium (III) (Ir (npy) zacac), tris[2-(3-methyl-2-pyridyl)phenyl] iridium (Ir(3mppy)₃), bis(2-(3,5-dimethylphenyl) quinoline-C2,N′) (acetylacetonate) iridium (III) (Ir(dmpq)₂acac), bis(2-(2′-benzothienyl)-pyridine-N,C3′) iridium (acetylacetonate) (Ir(btp)₂(acac)), 4-(dicyanomethylene)-2-methyl-6-[2-(2,3,6,7-tetrahydro-1H,5H-benzo[ij] quinolizin-9-yl) vinyl]-4H-pyran (DCM2), 5,6,11,12-tetraphenyltetracene, tris(2-(3,5-dimethylphenyl) quinoline-C2,N′) iridium (III) (Ir(dmpq)₃), 2,8-di-tert-butyl-5,11-bis(4-tert-butylphenyl)-6,12-diphenyltetracene (TBRb), and 10-(4-(4,6-diphenyl-1,3,5-triazol-2-yl)phenyl)-9,9-dimethyl-9,10-dihydroacridine (DMAC-TRZ);
the host material is one or more of the following: Alq₃, 4,4′-bis(N-carbazole)-1,1′-biphenyl (CBP), 4,4′-bis(2,2-diphenyl-ethen-1-yl)-4,4′-dimethylphenyl (p-DMDPVBi), 4,4′-bis(2,2-distyryl)-1,1′-biphenyl (DPVBi), 2-tert-butyl-9,10-bis(2-naphthyl) anthracene (TBADN), diphenyl[4-(triphenylsilyl)phenyl] phosphine oxide (TSPO1), 3-(3-(9H-carbazol-9-yl)phenyl)benzofuran[2,3-b]pyridine (PCz-BFP), 2,4,6-tris[3-(diphenylphosphinyloxy)phenyl]-1,3,5-triazole (PO-T2T), 2,4,6-tris(3-(carbazol-9-yl)phenyl)-1,3,5-triazine (TCPZ), 4,4′-bis(triphenylsilyl)-1,1′-biphenyl (BSB), 2,7-bis[9,9-bis(4-methylphenyl)-fluoren-2-yl]-9,9-bis(4-methylphenyl) fluorene (TDAF), and 3′,3″,3′-(1,3,5-triazine-2,4,6-triyl)tris(([1,1′-biphenyl]-3-carbonitrile)) (CN-T2T).

7. The planar light-emitting transistor capable of surface light source emission as claimed in claim 1, wherein the semiconductor charge transport layer, the charge buffer layer, and the light-emitting unit all have a thickness of nanometer to submicron level.

8. The planar light-emitting transistor capable of surface light source emission as claimed in claim 7, wherein the planar light-emitting transistor capable of surface light source emission can emit a planar light matched in color to the light-emitting unit under an externally applied voltage; and/or, the planar light-emitting transistor capable of surface light source emission can have a device structure of top or bottom light emission.

9. A preparation method for the planar light-emitting transistor capable of surface light source emission as claimed in claim 1, comprising the following steps: arranging a charge buffer layer under a drain electrode or a source electrode, wherein
preferably, the charge buffer layer is arranged between the drain electrode (or the source electrode) and a semiconductor charge transport layer, or between the semiconductor charge transport layer and a light-emitting unit;
the semiconductor charge transport layer, the light-emitting unit, the charge buffer layer, the source electrode, and the drain electrode all have the meanings as indicated above;
preferably, a structure comprising the semiconductor charge transport layer, the charge buffer layer, and the light-emitting unit is taken as an active layer, wherein the active layer is prepared by any one of methods selected from the following:
method I: depositing a film of a small molecule material on the dielectric layers and electrodes described above by vacuum thermal evaporation in an evaporation cavity to obtain the active layer;
method II: spin-coating a solution of an active layer material on the dielectric layers and electrodes described above by spin coating to obtain the active layer;
method III: preparing and growing a monocrystal film of a small molecule material by solution epitaxy: dissolving the small molecule material in a solvent that is not miscible with water, slowly adding the obtained uniformly mixed solution dropwise to a water surface, spreading the mixed solution on the water surface, and volatilizing the solvent to obtain the monocrystal film; inserting a support substrate with a dielectric layer into water, and transferring the monocrystal film to the surface of the dielectric layer to obtain the active layer; and
method IV: preparing a monocrystal film of a small molecule material by solution shearing: dissolving the small molecule material in an organic solvent, adding the obtained uniformly mixed solution dropwise to a support substrate with a dielectric layer, and slowly shearing and stretching the added solution to form an active layer.

10. Use of the planar light-emitting transistor capable of surface light source emission as claimed in claim 1 in fields of wearable devices, illumination (preferably white light illumination), illumination display, and lasers.
